(19) United States
(12) Patent Application Publication
(10) Pub. No.: US 2012/0164328 A1
(43) Pub. Date: Jun. 28, 2012

(54) FILM FORMATION METHOD AND STORAGE MEDIUM

(75) Inventors: Yasuhiko Kojima, Nirasaki-shi (JP); Shuji Azumo, Nirasaki-shi (JP)

(73) Assignee: TOKYO ELECTRON LIMITED, Tokyo (JP)

(21) Appl. No.: 13/054,361

(22) PCT Filed: Aug. 26, 2010
(86) PCT No.: PCT/JP2010/064573

§ 371 Date: Jan. 14, 2011

(30) Foreign Application Priority Data
Sep. 17, 2009 (JP) 2009-215414

(51) Int. Cl. C23C 16/44; B05D 1/36; C25D 5/00

(52) U.S. Cl. 427/250; 205/186; 118/697

(57) ABSTRACT

A substrate is transferred to a processing container, and a film formation raw material containing cobalt amidinate and a reducing agent containing a carbonic acid in a vapor phase are introduced into the processing container, thereby a Co film is formed on the substrate.

### TECHNICAL FIELD

The present invention relates to a film formation method for forming a film, such as a Co film or the like, by CVD method, and a storage medium.

### BACKGROUND ART

Recently, as semiconductor devices have higher speed and wiring patterns get smaller, Cu having higher conductivity than Al and also having high electromigration resistance and the like has been in the spotlight as the wiring. Electroplating is used to form Cu wiring, and studies have been made to use Co instead of Cu, which is generally used, as a seed of Cu wiring formed by electroplating in order to improve embedding characteristic.

Meanwhile, CoSi_{X} or NiSi_{X} that is obtained by forming a Co film or a Ni film and performing silicidation is used in a contact of a gate electrode and source/drain electrodes with Si in a MOS-type semiconductor.

Although a physical vapor deposition (PVD) method, which is represented by sputtering method, is much used as a method for forming a Co film or a Ni film, the PVD method has a drawback in that step coverage becomes poor as semiconductor devices get smaller.

Accordingly, a chemical vapor deposition (CVD) method for forming a Co film or a Ni film on a substrate in a pyrolysis reaction using a raw material gas containing Co or Ni or in a reduction reaction using a reducing gas of the raw material gas is used as a method for forming the Co film or the Ni film. The Co film or the Ni film formed by CVD method has good step coverage and good film formation characteristic in a narrow, long, and deep pattern. Accordingly, the Co film or the Ni film formed by CVD method has high conformity to a micro pattern and is very appropriate as a seed layer or a contact layer of Cu plating.

Regarding the Co film formed by CVD method, an academic paper (for example, nature materials/Vol. 2 Nov. 2003 pp 749-754) using cobalt amidinate as a film formation raw material (precursor) and using H₂ or NH₃ as a reducing agent has been presented.

### DISCLOSURE OF THE INVENTION

### Technical Problem

However, in CVD using cobalt amidinate and H₂, reactivity is low and impurities tend to remain in a film, thereby leading to poor film quality. Also, if high temperature film formation is performed in order to solve the problem of low reactivity, surface characters are deteriorated due to agglomeration of Co. Also, in CVD using cobalt amidinate and NH₃, a Co nitride is formed, thereby forcing a film to have high resistance.

Although a Ni film may also be formed by CVD method using nickel amidinate and using H₂ or NH₃ as a reducing agent, the same problems are caused.

Accordingly, an objective of the present invention is to provide a film formation method for forming a Co film having good surface state and good film quality at low temperature by using cobalt amidinate as a film formation raw material.

Another objective of the present invention is to provide a film formation method for forming a Ni film having good surface state and good film quality at low temperature by is using nickel amidinate as a film formation raw material.

A further objective of the present invention is to provide a storage medium having stored thereon a program for executing the film formation methods.

### Technical Solution

The present inventors have studied in order to achieve the objectives. As a result, it has been found that if cobalt amidinate or nickel amidinate is used as a film formation raw material, a Co film or a Ni film can be formed at low temperature and at a film formation speed applicable to a semiconductor process by using a carbonic acid as a reducing agent, and thus surface characters and film quality can be improved, thereby completing the present invention.

That is, according to an aspect of the present invention, there is provided a film formation method including: transferring a substrate to a processing container; and introducing a film formation raw material containing cobalt amidinate and a reducing agent containing a carbonic acid in a vapor phase into the processing container, thereby a Co film is formed on the substrate.

According to another aspect of the present invention, there is provided a film formation method including: transferring a substrate to a processing container; and introducing a film formation raw material containing nickel amidinate and a reducing agent containing a carbonic acid in a vapor phase into the processing container, thereby a Ni film is formed on the substrate.

According to another aspect of the present invention, there is provided a storage medium operating on a computer, having stored thereon a program for controlling a film formation apparatus and controlling the film formation apparatus on the computer, wherein the program performs, when the program is executed, a film formation method including transferring a substrate to a processing container and introducing a film formation raw material containing cobalt amidinate and a reducing agent containing a carbonic acid in a vapor phase into the processing container to form a Co film on the substrate.

According to another aspect of the present invention, there is provided a storage medium operating on a computer, having stored thereon a program for controlling a film formation apparatus and controlling the film formation apparatus on the computer, wherein the program performs, when the program is executed, a film formation method including transferring a substrate to a processing container and introducing a film is formation raw material containing nickel amidinate and a reducing agent containing a carbonic acid in a vapor phase into the processing container to form a Ni film on the substrate.

### BRIEF DESCRIPTION OF THE DRAWINGS

FIG. 1 is a schematic cross-section showing an embodiment of a film formation apparatus for performing a film formation method according to the present invention.

FIG. 2 is a timing chart showing an embodiment of a film formation sequence.

FIG. 3 is a timing chart showing another embodiment of a film formation sequence.

### BEST MODE FOR CARRYING OUT THE INVENTION

### Mode for Carrying Out the Invention

Hereinafter, embodiments of the present invention will be explained with reference to the attached drawings.

<Embodiment of Film Formation Apparatus for Performing Film Formation Method of the Present Invention>

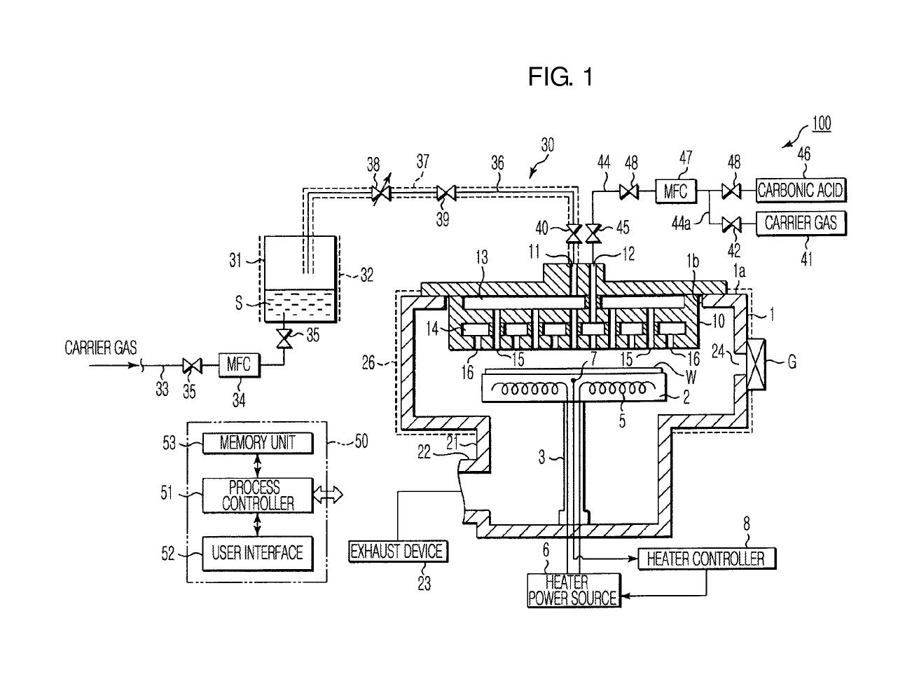

FIG. 1 is a schematic cross-section showing an embodiment of a film formation apparatus for performing a film formation method according to the present invention.

A film formation apparatus 100 includes a chamber 1 that has a substantially cylindrical shape and is hermetically sealed. A susceptor 2 for horizontally holding a semiconductor wafer W that is a substrate to be processed is disposed in the chamber 1 while being held by a support member 3 that has a cylindrical shape and is formed on a middle portion of a bottom surface of the susceptor 2. The susceptor 2 is formed of ceramic such as AlN or the like. Also, a heater 5 is embedded in the susceptor 2, and a heater power source 6 is connected to the heater 5. Meanwhile, a thermocouple 7 is formed in the vicinity of a top surface of the susceptor 2, and a signal of the thermocouple 7 is transmitted to a heater controller 8. And, the heater controller 8 transmits a command to the heater power source 6 according to the signal of the thermocouple 7, and controls heating of the heater 5 to control the wafer W to have a predetermined temperature. Also, three wafer elevating fins (not shown) are formed on the susceptor 2 to protrude from and dent into a surface of the susceptor 2, such that the wafer elevating fins protrude from the surface of the susceptor 2 when the wafer W is transferred.

A hole 1b having a circular shape is formed in a ceiling wall 1a of the chamber 1, and a shower head 10 is inserted in the hole 1b to protrude into the chamber 1.

A first introduction path 11 through which a film formation raw material gas is introduced and a second introduction path 12 through which a reducing agent is introduced into the chamber 1 are formed in an upper portion of the shower head 10 for ejecting a gas for film formation supplied from a gas supply device 30, which will be explained later, into the chamber 1. The first introduction path 11 and the second introduction path 12 are separately formed in the shower head 10, and the film formation raw material gas and the reducing agent are mixed after being ejected.

Spaces 13 and 14 are formed in the shower head 10 vertically in two tiers. The first introduction path 11 is connected to the upper space 13, and first gas ejection paths 15 extend from the space 13 to a bottom surface of the shower head 10. The second introduction path 12 is connected to the lower space 14, and second gas ejection paths 16 extend from the space 14 to the bottom surface of the shower head 10. That is, the shower head 10 is configured such that a film formation raw material gas and a carbonic acid gas as a reducing agent are respectively independently ejected from the ejection paths 15 and 16.

An exhaust chamber 21 protruding downward is formed at a bottom wall of the chamber 1. An exhaust pipe 22 is connected to a side surface of the exhaust chamber 21, and an exhaust device 23 including a vacuum pump, a pressure control valve, or the like is connected to the exhaust pipe 22. And, an inner part of the chamber 1 can be depressurized to a predetermined vacuum level by operating the exhaust device 23.

An inlet/outlet 24 for transferring the wafer W between the chamber 1 and a wafer transfer chamber (not shown) and a gate valve G for opening and closing the inlet/outlet 24 are formed in a side wall of the chamber 1. Also, a heater 26 is formed along walls of the chamber 1 so that temperatures of inner walls of the chamber 1 can be controlled during film formation.

The gas supply device 30 includes a film formation raw material tank 31 for storing a film formation raw material S. The film formation raw material S is cobalt amidinate when a Co film is to be formed, and is nickel amidinate when a Ni film is to be formed. The cobalt amidinate may be, for example, bis(N-tert-butyl-N′-ethyl-propionamidinate) cobalt (II) (Co(tBu-Et-Et-amd)₂). Also, the nickel amidinate may be, for example, bis(N,N′-di-tert-butyl-acetamidinate) nickel (II) (Ni(tBu-amd)₂).

Since these film formation raw materials S are generally solid at room temperature, a heater 32 is formed around the film formation raw material tank 31 to heat and liquefy a film formation raw material. Also, a carrier gas pipe 33 for supplying a carrier gas, for example, an Ar gas, is inserted into a bottom portion of the film formation raw material tank 31. A mass flow controller 34 and two valves 35 with the mass flow controller 34 interposed therebetween are formed in the carrier gas pipe 33. Also, one end of a film formation raw material supply pipe 36 is inserted downward into a upper part of the film formation raw material tank 31, and the other end of the film formation raw material supply pipe 36 is connected to the first introduction path 11. And, a film formation raw material heated and liquefied by the heater 32 is bubbled by a carrier gas supplied from the carrier gas pipe 33, passes in a gas phase through the film formation raw material pipe 36 and the first introduction path 11, and is supplied to the shower head 10. A heater 37 is formed around the film formation raw material supply pipe 36 to prevent the film formation raw material in the gas phase from being liquefied. Also, a flow rate regulating valve 38, an on/off valve 39 disposed downstream from the flow rate regulating valve 38, and an on/off valve 40 disposed closest to the first introduction path 11 are formed in the film formation raw material supply pipe 36.

A reducing agent supply pipe 44 for supplying a carbonic gas as a reducing agent is connected to the second introduction path 12 of the shower head 10. A carbonic acid supply source 46 for supplying the carbonic acid as the reducing agent is connected to the reducing agent supply pipe 44. Also, a valve 45 is installed in the vicinity of the second introduction path 12 in the reducing agent supply pipe 44. Also, a mass flow controller 47 and two valves 48 with the mass flow controller 47 interposed therebetween are formed in the reducing agent supply pipe 44. A carrier gas supply pipe 44a diverges from the upstream side of the mass flow controller 47 of the reducing agent supply pipe 44, and a carrier gas supply source 41 is connected to the carrier gas pipe 44a. And, a carbonic acid gas as a reducing agent for reducing cobalt amidinate or nickel amidinate which is a film formation raw material is supplied from the carbonic acid supply source 46 into the chamber 1 through the reducing agent supply pipe 44 and the shower head 10. Also, a carrier gas, for example, an Ar gas, is supplied from the carrier gas supply source 41 into the chamber 1 through the carrier gas supply pipe 44a, the reducing gas supply pipe 44, and the shower head 10. A formic acid (HCOOH) and an acetic acid (CH₃COOH) may be very appropriately used as the carbonic acid which is the reducing agent.

The film formation apparatus includes a control unit 50, and the control unit 50 controls each of elements, for example, the heater power source 6, the exhaust device 23, the mass flow controllers 34 and 47, the flow rate regulating valve 38, the valves 35, 39, 40, 45, and 48, and so on, or controls a temperature of the susceptor 2 by means of the heater controller 8, and so on. The control unit 50 includes a process controller 51 including a microprocessor (computer), a user interface 52, and a memory unit 53. Each element of the film formation apparatus 100 is electrically connected to the process controller 51 to be controlled by the process controller 51. The user interface 52 is connected to the process controller 51, and includes a keyboard with which an operator executes an input operation of a command, or the like in order to manage each element of the film formation apparatus 100, a display on which an operating state of each element of the film formation apparatus 100 is visually displayed, and so on. The memory unit 53 is also connected to the process controller 51, and a control program for implementing various processes performed in the film formation apparatus 100 under the control of the process controller 51 or a control program for implementing a predetermined process in each element of the film formation apparatus 100 according to process conditions, that is, process recipes, various databases, and the like, are accommodated in the memory unit 53. The process recipes are stored in a storage medium (not shown) in the memory unit 53. The storage medium may be a stationary medium, such as a hard disk or the like, or a portable medium such as a CD ROM, a DVD, a flash memory, or the like. Also, the recipes may be appropriately transmitted from another device through, for example, a dedicated line.

And if necessary, a desired process is performed in the film formation apparatus 100 under the control of the process controller 51 by reading a predetermined process recipe from the memory unit 53 in response to an instruction or the like from the user interface 52 and executing the process recipe in the process controller 51.

<Embodiment where Film formation Method of the Present Invention is Used to Form Co Film>

An embodiment where a film formation method of the present invention performed by using the film formation apparatus constructed as described above is used to form a Co film will now be explained.

In order to form a Co film, first, the gate valve G is opened, and the wafer W is introduced into the chamber 1 by a transfer device (not shown) and placed on the susceptor 2. If the Co film is used as a seed of Cu wiring formed by electroplating, the is wafer W having a surface on which an organic insulating film or a SiOxCy insulating film (x and y are integers) is formed as a base is used. Also, if the Co film is used as a contact layer, the wafer W having a surface on which a polysilicon film is formed or on which a silicon substrate surface that is to become source/drain electrodes is exposed is used.

Next, air in the chamber 1 is evacuated by the exhaust device 23 such that a pressure in the chamber 1 is 1.33 to 1333 Pa (10 mTorr to 10 Torr), the susceptor 2 is heated by the heater 5 such that a temperature of the susceptor 2 (wafer temperature) is equal to or less than 300° C., preferably, 120 to 250° C., and a carrier gas is supplied at a flow rate of 100 to 1500 mL/min (sccm) into the chamber 1 through the carrier gas supply source 41, the carrier gas supply pipe 44a, the reducing agent supply pipe 44, and the shower head 10 to perform stabilization.

When conditions are stabilized after the stabilization is performed for a predetermined period of time, a carrier gas is supplied at a flow rate of 100 to 1500 mL/min (sccm) from the pipe 33 into the film formation raw material tank 31, which is heated by the heater 32 to a temperature of, for example, 60 to 120° C., vapors of cobalt amidinate, for example, bis(N-tert-butyl-N′-ethyl-propionamidinate) cobalt (II) (Co(tBu-Et-Et-amd)₂), are introduced as a film formation raw material by bubbling from the film formation raw material supply pipe 36 into the chamber 1 through the shower head 10, and a carbonic acid in a gas phase is additionally introduced as a reducing agent from the carbonic acid supply source 46 into the chamber 1 through the reducing agent supply pipe 44 and the shower head 10, thereby film formation of the Co film is started.

The cobalt amidinate has a structural formula as shown in Formula (1), and is typically liquid at room temperature. As shown in Formula (1), a Co atom of the cobalt amidinate is coupled to four N atoms, and the bond is broken by the carbonic acid as the reducing agent, thereby the Co film is obtained.

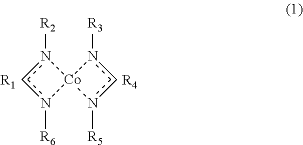

However, R₁, R₂, R₃, R₄, R₅, and R₆ are hydrocarbon-based functional groups.

A vapor pressure of liquid of Co(tBu-Et-Et-amd)₂ as a specific example of the cobalt amidinate is equal to or less than 3990 Pa (30 Torr) at 110° C. A structural formula of Co(tBu-Et-Et-amd)₂ is shown as Formula (2).

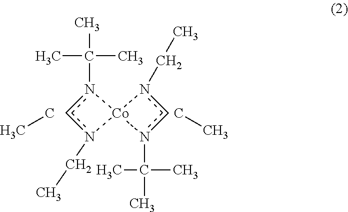

A formic acid (HCOOH) and an acetic acid (CH₃COOH) may be very appropriately used as the carbonic acid which is the reducing agent as described above. Among carbonic acids, the acids (HCOOH) and (CH₃COOH) have particularly high reducibility. Among the acids (HCOOH) and (CH₃COOH), the formic acid (HCOOH) is more appropriate.

If Co(tBu-Et-Et-amd)₂ is used, a flow rate of the cobalt amidinate during film formation under conditions where a temperature of a raw material container is 80° C., a pressure in the processing container is 10 Torr, and so on is about 2 to 30 mL/min (sccm) when a flow rate of the carrier gas is 100 to 1500 mL/min (sccm). Also, a flow rate of the carbonic acid as the reducing agent is about 1 to 2000 mL/min (sccm).

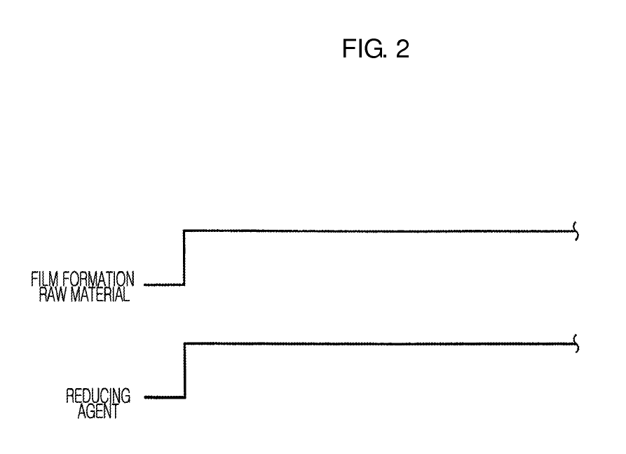

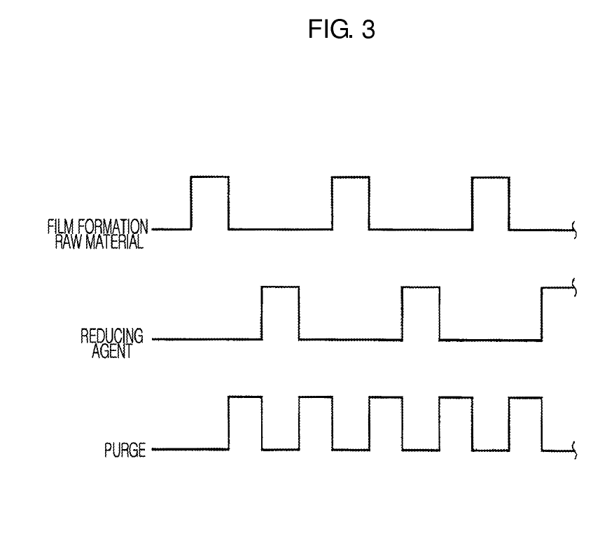

A film formation sequence may be general CVD that simultaneously supplies a film formation raw material (cobalt amidinate in this case) and a carbonic acid which is a reducing agent as shown in FIG. 2. Also, a so-called ALD method that alternately supplies a film formation raw material (cobalt amidinate) and a carbonic acid as a reducing agent with purging interposed therebetween may be used as shown in FIG. 3. The purging may be performed by supplying a carrier gas. Due to the ALD method, a film formation temperature can be further reduced.

And, after the Co film is formed in this way, a purging process is performed. In the purging process, after supply of the cobalt amidinate is stopped by stopping supply of the carrier gas to the film formation raw material tank 31, in a state where the vacuum pump of the exhaust device 23 is fully extended, a carrier gas is supplied as a purging gas from the carrier gas supply source 41 into the chamber 1 to purge the chamber 1. In this case, in order to purge the chamber 1 as rapidly as possible, it is preferable that the supply of the carrier gas may be intermittently performed.

After the purging process is finished, the gate valve G is opened and the wafer W is transferred out through the inlet/outlet 24 by the transfer device (not shown). Accordingly, a series of processes performed on one unit of wafer W is finished.

As such, if CVD is performed to form a film by using a carbonic acid as a reducing agent on cobalt amidinate which is a film formation raw material, since the carbonic acid has a high reducing power with respect to the cobalt amidinate, a Co film can be formed at a practical film formation speed at a low temperature of 120 to 300° C. Among carbonic acids, if a formic acid (HCOOH) or an acetic acid (CH₃COOH) is used, a particularly high reduction power can be achieved, and a Co film having good film quality with less impurities can be formed at a practical film formation rate at a low temperature of 120 to 250° C. Also, since the Co film can be formed at a practical film formation rate at low temperature as described, agglomeration of Co rarely occurs, thereby enabling obtaining of a Co film having improved surface characters.

The Co film formed as described above is very appropriate as a seed film of Cu wiring formed by electroplating. Also, the Co film may be used as a base film of a CVD-Cu film. Also, if the Co film is used as a contact layer, the Co film is formed as described above on a surface of a silicon substrate or a polysilicon film, and then heat treatment for silicidation is performed in an inert gas atmosphere or a reducing gas atmosphere. It is preferable that a temperature of the heat treatment in this case is 450 to 800° C.

<Embodiment where Film Formation Method of the Present Invention is Used to Form Ni Film>

An embodiment where a film formation method of the present invention performed by using the film formation apparatus is used to form a Ni film will now be explained.

In order to form a Ni film, first, the gate valve G is opened, and the wafer W is introduced into the chamber 1 by the transfer device (not shown) and placed on the susceptor 2. If the Ni film is used as a contact layer, the wafer W having a surface on is which a polysilicon film is formed or on which a silicon substrate surface that is to become source/drain electrodes is exposed is used.

Next, air in the chamber 1 is evacuated by the exhaust device 23 such that a pressure in the chamber 1 is 1.33 to 1333 Pa (10 mTorr to 10 Torr), the susceptor 2 is heated by the heater 5 such that a temperature of the susceptor 2 (wafer temperature) is equal to or less than 300° C., preferably, 120 to 250° C., and a carrier gas is supplied at a flow rate of 100 to 1500 mL/min (sccm) into the chamber 1 through the carrier gas supply source 41, the carrier gas supply pipe 44a, the reducing agent supply pipe 44, and the shower head 10 to perform stabilization.

When conditions are stabilized after the stabilization is performed for a predetermined period of time, a carrier gas is supplied at a flow rate of 100 to 1500 mL/min (sccm) from the pipe 33 into the film formation raw material tank 31, which is heated by the heater 32 to a temperature of, for example, 60 to 120° C., vapors of nickel amidinate, for example, bis(N,N′-di-tert-butyl-acetamidinate) nickel (II) (Ni(tBu-amd)₂), are introduced as a film formation raw material by bubbling from the film formation raw material supply pipe 36 into the chamber 1 through the shower head 10, and a carbonic acid in a gas phase is additionally introduced as a reducing agent from the carbonic acid supply source 46 into the chamber 1 through the reducing agent supply pipe 44 and the shower head 10, thereby a film formation of the Ni film is started.

The nickel amidinate has a structural formula as shown in Formula (3), and is typically solid at room temperature and has a melting point of 80 to 90° C. As shown in Formula (3), a Ni atom of the nickel amidinate is coupled to four N atoms, and the bond is broken by the carbonic acid which is the reducing agent, thereby the Ni film is obtained.

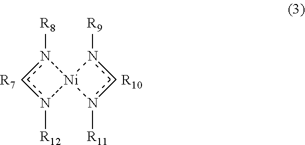

However, R₇, R₈, R₉, R₁₀, R₁₁, and R₁₂ are hydrocarbon-based functional groups.

A melting point and a vapor pressure of liquid of Ni(tBu-amd)₂ as a specific example of the nickel amidinate are respectively 87° C. and equal to or less than 26.6 Pa (200 Torr) at 90° C. A structural formula of the Ni(tBu-amd)₂ is shown as Formula (4).

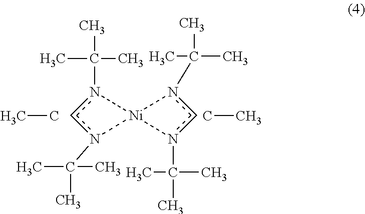

A formic acid (HCOOH) and an acetic acid (CH₃COOH) may be very appropriately used as the carbonic acid which is the reducing agent as described above. Among carbonic acids, the acids (HCOOH) and (CH₃COOH) have particularly high reducibility. Among the acids (HCOOH) and (CH₃COOH), the formic acid (HCOOH) is more appropriate.

If the Ni(tBu-amd)₂ is used, a flow rate of the nickel amidinate during film formation under conditions where a temperature of a raw material container is 90° C., a pressure in the processing container is 10 Torr, and so on is about 2 to 30 mL/min (sccm) when a flow rate of the carrier gas ranges from 100 to 1500 mL/min (sccm). Also, a flow rate of the carbonic acid as the reducing agent is about 10 to 2000 mL/min (sccm).

A film formation sequence may be general CVD that simultaneously supplies a film formation raw material (nickel amidinate in this case) and a carbonic acid which is a reducing agent as shown in FIG. 2. Also, a so-called ALD method that alternately supplies a film formation raw material (nickel amidinate) and a carbonic acid as a reducing agent with purging interposed therebetween may be used as shown in FIG. 3. The purging may be performed by supplying a carrier gas. Due to the ALD method, a film formation temperature can be further reduced.

And, after the Ni film is formed in this way, a purging process is performed. In the purging process, after supply of the cobalt amidinate is stopped by stopping supply of the carrier gas to the film formation raw material tank 31, in a state where the vacuum pump of the exhaust device 23 is fully extended, a carrier gas is supplied as a purging gas from the carrier gas supply source 41 into the chamber 1 to purge the chamber 1. In this case, in order to purge the chamber 1 as rapidly as possible, it is preferable that the supply of the carrier gas may be intermittently performed.

After the purging process is finished, the gate valve G is opened and the wafer W is transferred out through the inlet/outlet 24 by the transfer device. Accordingly, a series of processes performed on one unit of wafer W is finished.

As such, if CVD is performed to form a film by using a carbonic acid as a reducing agent on nickel amidinate which is a film formation raw material, since the carbonic acid has a high reducing power with respect to the nickel amidinate, a Ni film can be formed at a practical film formation speed at a low temperature of 120 to 300° C. Among carbonic acids, if a formic acid (HCOOH) or an acetic acid (CH₃COOH) is used, a particularly high reducing power can be achieved, and a Ni film having good film quality with less impurities can be formed at a practical film formation rate at a low temperature of 120 to 250° C. Also, since the Ni film can be formed at a practical film formation rate at low temperature as described, agglomeration of Ni rarely occurs, thereby enabling to obtain a Ni film having improved surface characters.

The Ni film formed as described above is very appropriate as a contact layer. If the Ni film is used as a contact layer, the Ni film is formed as described above on a surface of a silicon substrate or a polysilicon film, and then heat treatment for silicidation is performed in an inert gas atmosphere or a reducing gas atmosphere. It is preferable that a temperature of the heat treatment in this case is 300 to 700° C.

Although a carbonic acid is used as a reducing agent for cobalt amidinate or nickel amidinate which is a film formation raw material as described above, since the carbonic acid has a high reducing power with respect to the cobalt amidinate and the nickel amidinate, a Co film or a Ni film having good film quality with less impurities can be formed at a practical film formation rate at low temperature by CVD method. Also, since the Co film or the Ni film can be formed at a practical film formation rate at low temperature as described, agglomeration of Co or Ni rarely occurs, thereby enabling is obtaining of a Co film and a Ni film having improved surface characters.

<Another Application of the Present Invention>

Also, the present invention may be modified in various ways without being limited to the above-described embodiments. For example, although Co(tBu-Et-Et-amd)₂ is used as cobalt amidinate constituting a film formation raw material and Ni(tBu-amd)₂ is used as nickel amidinate constituting a film formation raw material in the embodiments, the present invention is not limited thereto. Also, a carbonic acid constituting a reducing agent is not limited to a formic acid and an acetic acid, and may be a propionic acid, a butyric acid, a valeric acid, or the like.

Also, methods for supplying cobalt amidinate and nickel amidinate as film formation raw materials are not limited to the methods exemplified in the embodiments, and various methods may be used. Also, a film formation apparatus is not limited to that in the embodiment, and may be any of various apparatuses including one that forms a device for generating plasma in order to promote decomposition of a film formation raw material gas.

And also, although a semiconductor wafer is used as a substrate to be processed, the present invention is not limited thereto and other substrates, such as a flat panel display (FPD) substrate or the like, may be used.

1. A film formation method comprising:
transferring a substrate to a processing container; and
introducing a film formation raw material containing cobalt amidinate and a reducing agent containing a carbonic acid in a vapor phase into the processing container, thereby a Co film is formed on the substrate.

2. The film formation method of claim 1, wherein the cobalt amidinate constituting the film formation raw material is bis(N-tert-butyl-N′-ethyl-propionamidinate) cobalt (II).

3. The film formation method of claim 1, after the forming of the Co film on the substrate, further comprising depositing Cu by electroplating.

4. The film formation method of claim 1, after the forming of the Co film on the substrate, further comprising depositing Cu by CVD.

5. The film formation method of claim 1, wherein the Co film is formed on silicon, and then heat treatment for silicidation is performed in an inert gas atmosphere or a reducing gas atmosphere.

6. The film formation method of claim 1, wherein a temperature of the substrate during film formation is equal to or less than 300° C.

7. The film formation method of claim 1, wherein the carbonic acid constituting the reducing agent is a formic acid.

8. The film formation method of claim 1, wherein the carbonic acid constituting the reducing agent is an acetic acid.

9. The film formation method of claim 1, wherein the film formation raw material and the reducing agent are simultaneously supplied into the processing container.

10. The film formation method of claim 1, wherein the film formation raw material and the reducing agent are alternately supplied, with a purging gas supplied between a supply of the film formation raw material and a supply of the reducing agent, into the processing container.

11. A film formation method comprising:
transferring a substrate to a processing container; and
introducing a film formation raw material containing nickel amidinate and a reducing agent containing a carbonic acid in a vapor phase into the processing container thereby a Ni film is formed on the substrate.

12. The film formation method of claim 11, wherein the nickel amidinate constituting the film formation raw material is bis(N,N′-di-tert-butyl-acetamidinate) nickel (II).

13. The film formation method of claim 11, wherein the Ni film is formed on silicon, and then heat treatment for silicidation is performed in an inert gas atmosphere or a reducing gas atmosphere.

14. The film formation method of claim 11, wherein a temperature of the substrate during film formation is equal to or less than 300° C.

15. The film formation method of claim 11, wherein the carbonic acid constituting the reducing agent is a formic acid.

16. The film formation method of claim 11, wherein the carbonic acid constituting the reducing agent is an acetic acid.

17. The film formation method of claim 11, wherein the film formation raw material and the reducing agent are simultaneously supplied into the processing container.

18. The film formation method of claim 11, wherein the film formation raw material and the reducing agent are alternately supplied, with a purging gas supplied between a supply of the film formation raw material and a supply of the reducing agent, into the processing container.

19. A storage medium operating on a computer, having stored thereon a program for controlling a film formation apparatus and controlling the film formation apparatus on the computer, wherein the program performs, when the program is executed, a film formation method comprising transferring a substrate to a processing container and introducing a film formation raw material containing cobalt amidinate and a reducing agent containing a carbonic acid in a vapor phase into the processing container to form a Co film on the substrate.

20. A storage medium operating on a computer, having stored thereon a program for controlling a film formation apparatus and controlling the film formation is apparatus on the computer, wherein the program performs, when the program is executed, a film formation method comprising transferring a substrate to a processing container and introducing a film formation raw material containing nickel amidinate and a reducing agent containing a carbonic acid in a vapor phase into the processing container to form a Ni film on the substrate.
